(19) United States
(12) Patent Application Publication
(10) Pub. No.: US 2005/0129848 A1
(43) Pub. Date: Jun. 16, 2005

(54) Patterned deposition source unit and method of depositing thin film using the same

(75) Inventors: Sang-jun Choi, Gyeonggi-do (KR); Young-eal Kim, Gyeonggi-do (KR); Dong-joon Ma, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd, Gyeonggi-do (KR)

(21) Appl. No.: 10/902,798

(22) Filed: Aug. 2, 2004

(30) Foreign Application Priority Data
Dec. 16, 2003 (KR) 10-2003-0091947

(51) Int. Cl. C23C 16/00

(52) U.S. Cl. 427/249.1

(57) ABSTRACT

Provided is a patterned deposition source unit for forming a thin film on a substrate and a deposition method using the same. The patterned deposition source unit includes a main body that includes a loading section for loading a deposition material and a cover unit, which covers openings of the loading section and has a plurality of line shaped openings. The deposition material vaporized through line shaped openings of the cover unit can be vertically deposited on the substrate which moves back and forth over the main body. The method enables the improvement in the uniformity of a thin film by preventing dispersion of the deposition material in a conventional depositor, and the improvement in the density of a thin film by increasing vapor flux per unit area by reducing the distance between the deposition source unit and the substrate.

This application claims the priority of Korean Patent Application No. 2003-91947, filed on Dec. 16, 2003 in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a vaporization boat for depositing a thin film and a method of depositing a thin film using the same.

2. Description of the Related Art

A representative method for forming a thin film on a substrate is a sputtering method since it forms a relatively high density thin film when compared to other methods. However, this method requires an area of an upper surface of the vaporization boat to be almost twice the area of the substrate to maintain uniformity of the thin film at a desired level. Therefore, this method has a drawback in that the overall size of a vacuum chamber is increased due to the large area of the vaporization boat.

On the other hand, there is a method of depositing a thin film using a small boat called an electron beam (E-beam) deposition method. However, this method requires a sufficient distance between a deposition source unit and a substrate, which also requires an increase in size of a vacuum chamber, and another disadvantage of this method is that the density of a manufactured thin film is relatively low.

Therefore, research on a classic thermal deposition method that uses resistance heating, which is economically superior to the conventional methods of forming a thin film, is actively in process. The thermal deposition method is a general method for coating a metal such as aluminum, copper, or zinc on a variety of substrates composed of semiconductor, glass, or plastic, which are not largely restricted by a deposition material to be coated. Generally, a deposition material, i.e., a metal, is vaporized by electrical resistance heat in a self heat generating vessel called a “vaporization boat.”

FIG. 1 is a perspective view of a depositor according to a conventional resistance heat method.

Referring to FIG. 1, a substrate 14 is disposed in an upper part of a vacuum chamber 10a of a depositor 10. The substrate 14 can be loaded into the vacuum chamber 10a individually or continuously. A deposition material loaded on the vaporization boat 20 is evaporated by self heat of the vaporization boat 20 and adhered to a lower surface of the substrate 14, so that a thin film is formed on the lower surface of the substrate 14.

FIG. 2 is a perspective view for describing a conventional vaporization boat 20 used for the depositor of FIG. 1. Referring to FIG. 2, the vaporization boat 20 has a bar-shape having both ends 22 connected to a power source. A dimple cavity 26 in which a deposition material 28 is loaded, is formed on the central portion of the vaporization boat 20, and high resistance regions 24 are formed on both sides of the dimple cavity 26. The high resistance regions 24 are narrowed cross-sections having notches 24a.

The vaporization boat 20 is formed of a fireproof metal such as W, Ta, or Mo, and generates joule heat via a very high current i of approximately 100 A.

However, as in the electron beam deposition method, since the thermal resistance deposition method has a dispersion problem of vaporized deposition material, a sufficient distance between the deposition source unit and the substrate 14 is also required to obtain a uniform thickness of a thin film.

Also, there is a problem in that a thin film formed by the thermal deposition method is of a lower film density than a thin film formed by the sputtering method.

### SUMMARY OF THE INVENTION

To solve the above and/or other problems, the present invention provides a vaporization boat that can reduce the size of an evaporator by reducing the distance between a deposition source unit and a substrate and can increase uniformity and density of a thin film, and a method of depositing a thin film using the same.

The present invention also provides a vaporization boat that can form a uniform thickness thin film on a substrate and a method of applying the vaporization boat.

According to an aspect of the present invention, there is provided a vaporization boat comprising a main body that includes a loading section with a predetermined depth for loading a deposition material; and a cover unit formed of the same material as the main body, wherein the cover unit covers openings of the loading section and a plurality of line shaped openings.

The cover unit works as an auxiliary heat source, and a current is applied to the main body and the cover unit to heat the deposition material.

According to another aspect of the present invention, there is provided a deposition method for forming a thin film on a substrate using a patterned deposition source unit having a parallel line shaped pattern, the method comprising: loading the patterned deposition source unit in an evaporator; loading the substrate into the evaporator; vaporizing a source material by applying a current to the patterned deposition source unit; performing deposition for a first predetermined number of hours by moving the substrate along a perpendicular direction to the line shaped pattern of patterned deposition source unit; and performing deposition for a second predetermined number of hours by moving again the substrate in a perpendicular direction to the line shaped pattern of patterned deposition source unit after passing over the patterned deposition source unit and after rotating the substrate 900.

According to still another aspect of the present invention, there is provided a deposition method for forming a thin film on a substrate using a patterned deposition source unit having a parallel line shaped pattern, comprising the method comprising: (a) loading the patterned deposition source unit in an evaporator; (b) loading the substrate in the evaporator; (c) vaporizing a source material by applying a current to the patterned deposition source unit; (d) performing deposition for a predetermined hours by moving patterned deposition source unit in a first direction; and (e) performing deposition for a predetermined number of hours by moving the patterned deposition source unit in a second direction which is different from the first direction after rotating the substrate with a predetermined angle after (d).

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of an evaporator according to a conventional resistance heat method;

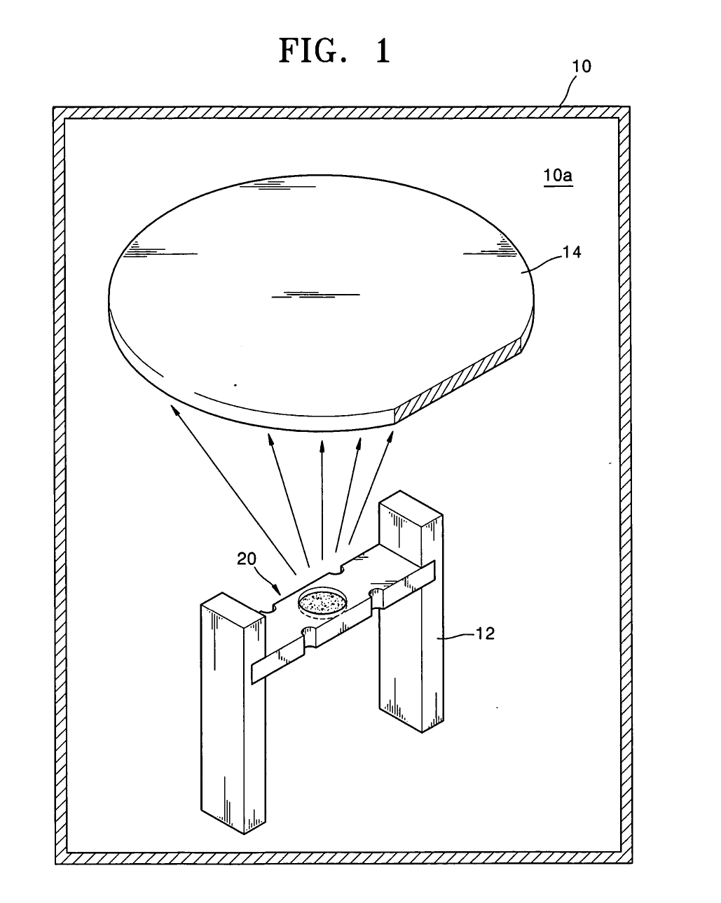

FIG. 2 is a perspective view of a conventional vaporization boat used for a depositor;

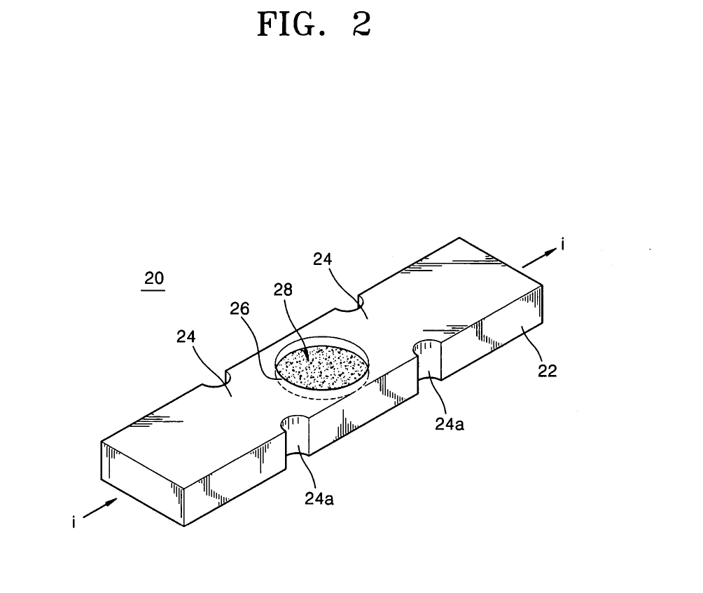

FIG. 3 is a perspective view of a vaporization boat according to an embodiment of the present invention;

FIG. 4 is a cross-sectional view of a vaporization boat taken at line I-I′ in FIG. 3; and

FIG. 5 is a perspective view for describing a deposition method by moving substrate within the depositor using a vaporization boat that includes a patterned cover unit with line shaped openings, according to an embodiment of the present invention.

### DETAILED DESCRIPTION OF THE INVENTION

Hereinafter, a vaporization boat that includes a patterned cover unit with a plurality of line shaped openings and a deposition method using the vaporization boat according to the present invention will now be described more fully with accompanying drawings.

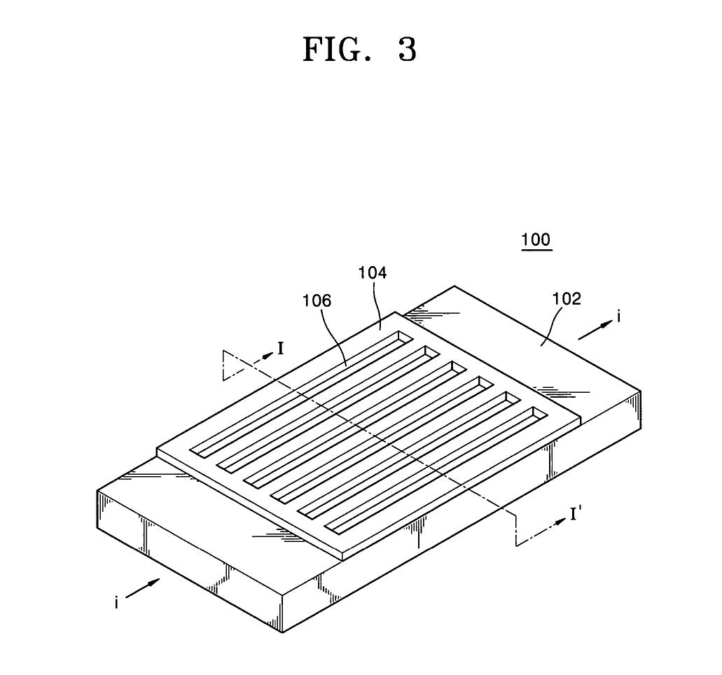

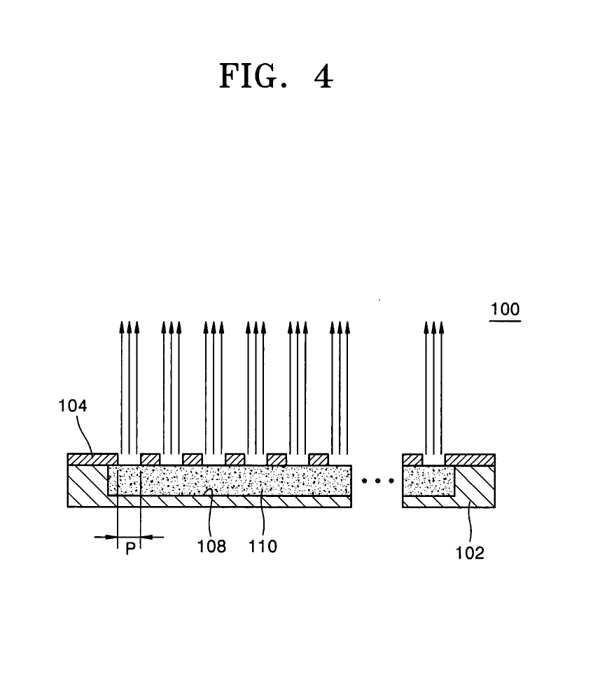

FIG. 3 is a perspective view of a vaporization boat according to an embodiment of the present invention. FIG. 4 is a cross-sectional view of a vaporization boat taken at line I-I′ in FIG. 3.

Referring to FIGS. 3 and 4, a vaporization boat 100 comprises a main body 102 that includes a loading section 108 having a dimple shape in a central portion in which a deposition material 110 is loaded, and a cover unit 104 that has a plurality of line shaped openings 106.

The plurality of line shaped openings 106 formed on the cover unit 104 each preferably has a width in a range of 1˜500 μm and preferably has a length formed to the same length as the deposition material 110. It is preferable that the main body 102 of the vaporization boat 100 is formed of a fireproof metal such as W, Ta, or Mo and that the deposition material 110 has a lower melting point than that of the main body 102 and the cover unit 104.

Joule heat is generated by allowing to flow a current of approximately 100 A on both ends of the main body 102 of the vaporization boat 100. The amount of heat generated thereby is i2R, where R is a value of a parallel resistance between the main body 102 and the deposition material 110 at a deposition temperature T.

The patterned cover unit 104 formed on the main body 102 also works as an auxiliary heat source for heating the deposition material 110 uniformly. Therefore, there is an advantage of obtaining a higher temperature using the present vaporization boat than using a conventional vaporization boat.

The heated deposition material 110 is vaporized, and deposited on a substrate loaded in the evaporator after passing through the plurality of openings 106 that are patterned to be parallel. The vaporized deposition material 110 that has passed through the openings 106 travels in vertical direction without dispersion.

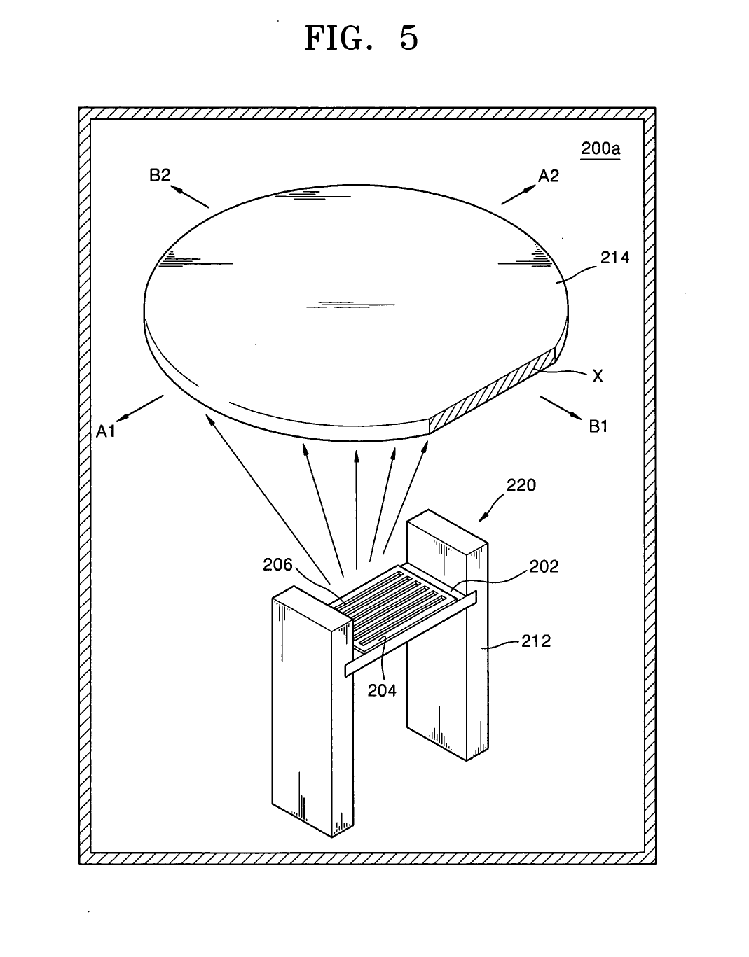

FIG. 5 is a perspective view for describing a deposition method by moving a substrate within the evaporator using a vaporization boat that includes a patterned cover unit having line shaped openings, according to an embodiment of the present invention.

Referring to FIG. 5, a method of depositing a thin film on a substrate using a vaporization boat having a patterned cover unit will be described as below. First, after loading a deposition material in a loading section of a vaporization boat 220, the loading section is covered with a cover unit 204. Then, a substrate 214 is loaded into a vacuum chamber 200a of an evaporator 200. At this time, the loaded substrate 214 is located at a distance from the vaporization boat 220.

Next, when applying a current to the main body 202 of the vaporization boat 220 and the patterned cover unit 204, the deposition material is vaporized. The deposition material vaporized passes through a plurality of line shaped openings 206 of the patterned cover unit 204. Then, the vaporized deposition material is deposited on the surface of the substrate 214 by moving the substrate 214 in a direction from B1 to B2. A direction from A1 to A2 indicates a length direction of the plurality of line shaped openings 206 formed on the patterned cover unit 204, and the direction from B1 to B2 indicates a vertical direction of the plurality of line shaped openings 206 formed on the patterned cover unit 204.

Next, when the substrate 214 has passed the vaporization boat 220 in the direction from B1 to B2, the substrate 214 is turned 90° and then deposition is performed repeatedly for a predetermined period of time by moving the substrate 214.

According to an aspect of the present invention, to form a thin film on a substrate 214, the deposition is performed repeatedly while moving the substrate 214 in the directions A1-A2 and B1-B2 alternately in the evaporator 200.

Also, the deposition is performed by moving the substrate 214 in the direction from B1 to B2 and from B2 to B1 back and forth in the evaporator 200.

The depositing time of the substrate 214 in the evaporator 200 by moving the substrate 214 from B1 to B2 and from B2 to B1 is equal.

In the embodiment of the present invention, a patterned cover unit is used to form a patterned deposition source unit, however, it is seen that a patterned deposition source unit can be formed by patterning the deposition material itself.

A method of depositing a thin film by rotating a substrate while moving back and forth is mainly described in the present embodiment. However, the deposition method can be modified to move the vaporization boat back and forth in first and second directions perpendicular to the line direction of the patterned deposition source unit, in which the substrate direction of the first direction is 90° difference from the substrate direction of the second direction.

The size of the vacuum chamber of the evaporator according to the present invention can be remarkably reduced by decreasing the distance between the deposition source unit and the substrate.

The deposition method according to the embodiment of the present invention is a method of depositing a thin film by moving a substrate over a vaporization boat having a patterned cover unit, and directions of the substrate when moving back and forth have 90° difference, thereby improving overall uniformity of a thin film.

Also, according to deposition method of the present invention, due to a reduced distance between the deposition source unit and the substrate and due to a directionality of vapor atoms, vapor atom flux per unit area is increases. Therefore, the thin film can be deposited in high density.

According to the present invention, since not only the main body of the vaporization boat, but also the patterned cover unit can act as a heating source, this method can easily be applied to deposit a source material having a high melting point.

While this invention has been particularly shown and described with reference to preferred embodiments thereof, it will be understood by those skilled in the art that various changes in form and details may be made therein without departing from the spirit and scope of the invention as defined by the appended claims.

1. A patterned deposition source unit comprising:
a main body that includes a loading section with a predetermined depth;
a cover unit that covers openings of the loading section and having a plurality of line shaped openings.

2. The patterned deposition source unit of claim 1, wherein the main body and the cover unit are formed of the same material.

3. The patterned deposition source unit of claim 1, wherein each opening formed on the cover unit has a width in a range of 1˜500 μm and has the same length as the length of the deposition material.

4. The patterned deposition source unit of claim 1, wherein the cover unit acts as an auxiliary heating source.

5. A method of depositing for forming a thin film on a substrate using a patterned deposition source unit having a parallel line shaped pattern, the method comprising:
(a) loading the patterned deposition source unit in an evaporator;
(b) loading the substrate into the evaporator;
(c) vaporizing a source material by applying a current to the patterned deposition source unit;
(d) performing deposition for a predetermined number of hours by moving the substrate in a first direction;
(e) rotating the substrate with a predetermined angle after passing through the patterned deposition source unit; and
(f) performing deposition for a predetermined number of hours by moving the substrate in a second direction which is different from the first direction.

6. The method of claim 5, wherein the first direction is a direction perpendicular to the length of the plurality of line shape patterns.

7. The method of claim 5, wherein the second direction is a direction opposite to the first direction.

8. The method of claim 5, wherein (d) through (f) are repeated.

9. The method of claim 8, wherein the number of times of performing (d) is equal to the number of times of performing (f).

10. A method of depositing a thin film on a substrate using a patterned deposition source unit having a parallel line shaped pattern, the method comprising:
(a) loading the patterned deposition source unit in an evaporator;
(b) loading the substrate in the evaporator;
(c) vaporizing a source material by applying a current to the patterned deposition source unit;
(d) performing deposition for a predetermined number of hours by moving patterned deposition source unit in a first direction;
(e) rotating the substrate with a predetermined angle and after (d); and
(f) performing deposition for a predetermined number of hours by moving the patterned deposition source unit in a second direction which is different from the first direction.

11. The method of claim 10, wherein the second direction is a direction opposite to the first direction.

12. The method of claim 11, wherein (d) through (f) are repeated.
